(19) United States
(12) Patent Application Publication
(10) Pub. No.: US 2007/0221968 A1
(43) Pub. Date: Sep. 27, 2007

(54) Transistor of semiconductor device and method for manufacturing the same

(75) Inventor: Jong Bum Park, Gyeonggi-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyeonggi-do (KR)

(21) Appl. No.: 11/647,753

(22) Filed: Dec. 29, 2006

(30) Foreign Application Priority Data
Mar. 21, 2006 (KR) 2006-25849

(51) Int. Cl. H01L 29/76

(52) U.S. Cl. 257/288

(57) ABSTRACT

A transistor of a semiconductor device comprises a gate dielectric layer formed over a semiconductor substrate and comprising a hafnium oxide; and a gate electrode formed over the gate dielectric layer.

### CROSS-REFERENCE TO RELATED APPLICATION

The present application claims priority to Korean patent application No. 10-2006-0025849, filed on Dec. 2, 2005, which is incorporated by reference in its entirety.

### BACKGROUND OF THE INVENTION

The invention relates to a transistor of a semiconductor device and a method for manufacturing the same. More particularly, the invention relates to a MOS or equivalent transistor of a semiconductor device with improved characteristics, and a method for manufacturing the same.

With advances in semiconductor devices toward high degrees of integration precision, transistors have continuously been required to have further improved capability. For this purpose, although a variety of research has been undertaken with respect to materials, processes, and the like, conventional transistors and methods for manufacturing the same have limits as described below.

Conventionally, a gate dielectric layer comprises a silicon oxide layer. In order to form a transistor having improved capability, it is necessary to secure a sufficient driving current and a suitable Vt of the transistor and to reduce a short channel effect through reduction in physical thickness or effective equivalent thickness (Tox) of the gate dielectric layer.

However, when the physical thickness of the gate dielectric layer comprising the silicon oxide layer is reduced to, for example, 35 Å or less, the transistor increases in current leakage caused by a tunneling effect, and decreases in reliability of the gate dielectric layer. In addition, if the gate dielectric layer becomes excessively thin, its insulating capability is likely to be broken, and thus the gate dielectric layer may not carry out its original function.

For this reason, a technique is required, which can improve the capability of the transistor by reducing the effective equivalent thickness while securing a sufficient physical thickness of the gate dielectric layer.

Conventionally, a gate electrode comprises a metal silicide layer and a doped polysilicon layer. As the semiconductor becomes highly integrated and requires a high degree of precision, there is an increasing demand of lowering resistance of the gate electrode. However, the gate electrode comprising the metal silicide layer and the doped polysilicon layer has a limit in lowering of resistance. Furthermore, the doped polysilicon layer may cause depletion in the gate electrode and increase in topology of the gate electrode, whereby the transistor increases in parasite capacitance, which deteriorates refresh characteristics of the transistor.

Moreover, conventionally, a dual poly gate process is employed to form a surface channel instead of a buried channel as an attempt to suppress the short channel effect resulting from the high integration of the semiconductor device. However, the dual poly gate process is complicated and may cause the depletion of the doped polysilicon layer in p-MOS.

For these reasons, there is a need for technology that can improve the characteristics of the transistor by, for example, reducing the resistance of the gate electrode, suppressing the depletion and the high topology of the gate electrode, and avoiding the short channel effect via a simple process.

### SUMMARY OF THE INVENTION

The invention is directed to a transistor of a semiconductor device with improved characteristics and a method for manufacturing the same.

In one embodiment, a transistor of a semiconductor device comprise: a gate dielectric layer formed over a semiconductor substrate and comprising a hafnium oxide, and a gate electrode formed over the gate dielectric layer.

The gate electrode preferably comprises a hafnium nitride, and the gate dielectric layer preferably comprises a hafnium oxide and a silicon oxide.

The gate dielectric layer preferably comprises a silicon-hafnium based composite oxide [(SiO₂)ₓ(HfO₂)_{y}](1≦x or y≦10). Here, the silicon-hafnium based composite oxide is preferably formed by atomic layer deposition.

The gate dielectric layer preferably comprises a hafnium oxide and at least one oxide selected from the group consisting of aluminum oxide, tantalum oxide, titanium oxide, and strontium titanium oxide.

The hafnium nitride preferably has a work function of 4.5 eV˜4.6 eV, and is preferably formed by atomic layer deposition.

The gate dielectric layer preferably has a thickness of 300 Å or less, and the gate electrode preferably has a thickness of 2,000 Å or less.

In another embodiment, a method for manufacturing a transistor of a semiconductor device comprises: forming a gate dielectric layer over a semiconductor substrate, the gate dielectric layer comprising a hafnium oxide; forming a gate electrode over the gate dielectric layer; and patterning the gate dielectric layer and the gate electrode to form a gate stack.

The gate electrode preferably comprises a hafnium nitride, and the gate dielectric layer preferably comprises a hafnium oxide and a silicon oxide.

The gate dielectric layer preferably comprises a silicon-hafnium based composite oxide [(SiO₂)x(HfO₂)y] (1≦x or y≦10). Here, the silicon-hafnium based composite oxide is preferably formed by atomic layer deposition.

The gate dielectric layer preferably comprises a hafnium oxide and at least one oxide selected from the group consisting of aluminum oxide, tantalum oxide, titanium oxide, and strontium titanium oxide.

The hafnium nitride preferably has a work function of 4.5 eV˜4.6 eV, and is preferably formed by atomic layer deposition.

The gate dielectric layer preferably has a thickness of 300 Å or less, and the gate electrode preferably has a thickness of 2,000 Å or less.

The gate dielectric layer and the gate electrode are preferably continuously formed by atomic deposition in the same chamber.

### BRIEF DESCRIPTION OF THE DRAWINGS

FIGS. 1a to 1c are cross-sectional views illustrating a method for manufacturing a transistor according to one embodiment of the invention.

### DESCRIPTION OF SPECIFIC EMBODIMENTS

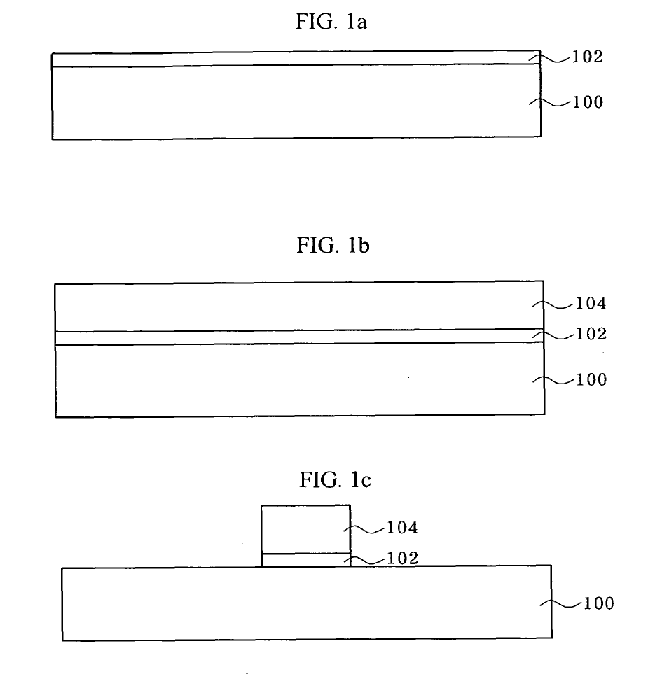

FIG. 1c illustrates a cross-section of a transistor according to one embodiment of the invention.

The transistor comprises a gate dielectric layer 102 formed over a selected region of a semiconductor substrate 100, and a gate electrode 104 formed over the gate dielectric layer 102.

In the illustrated transistor, the gate dielectric layer 102 comprises a hafnium oxide. For example, the gate dielectric layer may comprise the hafnium oxide and a silicon oxide.

Unlike a conventional technique wherein the gate dielectric layer comprises silicon oxide, the gate dielectric layer 102 comprises hafnium oxide, for example, hafnium oxide and silicon oxide, providing advantageous effects as follows.

Hafnium oxide has a higher dielectric constant than silicon oxide. When the gate dielectric layer 102 comprises hafnium oxide, it is possible to secure a sufficient driving current and a suitable Vt for the transistor and to avoid a short channel effect by reducing the effective equivalent thickness (Tox) while securing a sufficient physical thickness of the gate dielectric layer 102. At the same time, since the gate dielectric layer 102 has such a sufficient physical thickness, it is possible to suppress increase in current leakage caused by the tunneling effect, reduction in reliability of the gate dielectric layer 102, etc.

Meanwhile, the gate dielectric layer 102 may comprise a silicon-hafnium based composite oxide which can be expressed by [(SiO₂)x(HfO₂)y], where x and y are in the range of 1˜10, respectively. Since the silicon-hafnium based composite oxide also has a higher dielectric constant than the silicon oxide, the gate dielectric layer 102 comprising the silicon-hafnium based composite oxide can provide the advantageous effects as described above.

The silicon-hafnium based composite oxide of the gate dielectric layer 102 is preferably formed by atomic layer deposition. Irrespective of the advantageous effects by use of the silicon-hafnium based composite oxide having the high dielectric constant, if the silicon-hafnium based composite oxide is formed by typical chemical vapor deposition (CVD), the silicon-hafnium based composite oxide can be crystallized to make Vt non-uniform depending on a channel length, which possibly deteriorates reliability of a semiconductor device. On the other hand, when the silicon-hafnium based composite oxide is formed through the atomic layer deposition, the crystallization of the silicon-hafnium based composite oxide is suppressed so that a stable Vt can be obtained, thereby enhancing the reliability of the semiconductor device.

In the above description, the gate dielectric layer 102 comprises the silicon oxide in addition to the hafnium oxide, for example, the silicon-hafnium based composite oxide. Alternatively, the gate dielectric layer 102 may comprise other materials having a high dielectric constant as well as the hafnium oxide. For example, the gate dielectric layer 102 may comprise the hafnium oxide and at least one oxide selected from the group consisting of aluminum oxides, tantalum oxides, titanium oxides, and strontium titanium oxides.

Even in this case, the gate dielectric layer 102 has a higher dielectric constant than that of the conventional technique wherein the dielectric layer comprises the silicon oxide. As a result, the gate dielectric layer 102 has a sufficient physical thickness while being greatly reduced in effective equivalent thickness (Tox), enabling significant improvement in characteristics of the transistor. Furthermore, the hafnium oxide and the other materials having such a high dielectric constant are formed by the atomic layer deposition so that the crystallization of the gate dielectric layer 102 is suppressed, enhancing the reliability of the semiconductor device.

The gate dielectric layer 102 preferably has a thickness of 300 Å or less.

Meanwhile, in the transistor, the gate electrode 104 formed over the gate dielectric layer 102 preferably comprises a hafnium nitride.

When the gate electrode 104 of the transistor comprises the hafnium nitride, the transistor has advantageous effects described as follows.

The hafnium nitride has a lower resistance than a metal silicide layer and a doped polysilicon layer of the conventional gate electrode. Thus, when forming the gate electrode 104 using such a hafnium nitride, it is possible to efficiently reduce the resistance of the gate electrode 104. Additionally, since there is no need of using the doped polysilicon layer for the gate electrode 104, it is possible to avoid depletion of the gate electrode 104 or high topology of the gate electrode 104, whereby the increase in parasite capacitance and the deterioration of the refresh characteristics can be suppressed.

Meanwhile, the gate electrode 104 preferably comprises hafnium nitride having a work function of 4.5˜4.6 eV. As such, when the gate electrode 104 comprises the hafnium nitride having the work function near a mid band-gap energy, a surface channel is formed via suitable adjustment of Vt in n-MOS and p-MOS transistors, thereby suppressing the short channel effect caused by high integration of the semiconductor device. Therefore, it is possible to suppress the short channel effect without employing the dual poly gate process, which is complicated, and may cause the depletion in the doped polysilicon layer of the p-MOS.

The hafnium nitride of the gate electrode 104 can also be formed by the atomic layer deposition. As such, when the gate electrode 104 is formed by depositing the hafnium nitride through the atomic layer deposition, it is possible to continuously form the gate dielectric layer 102 and the gate electrode 104 in a single chamber. As a result, the process of forming the transistor of the semiconductor device and the structure of an apparatus therefor can be simplified.

The gate electrode preferably has a thickness of 2,000 Å or less.

FIGS. 1a to 1c are schematic cross-sectional views of the method for manufacturing the transistor according to one embodiment.

Referring to FIG. 1a, a gate dielectric layer 102 is formed over a semiconductor substrate 100.

The gate dielectric layer 102 comprises a hafnium oxide. For example, the gate dielectric layer may comprise a hafnium oxide and a silicon oxide.

As described above, when the gate dielectric layer 102 comprises the hafnium oxide, for example, the hafnium oxide and the silicon oxide, it is possible to secure a sufficient driving current and a suitable Vt for the transistor and to reduce a short channel effect by allowing the gate dielectric layer 102 to have a sufficiently increased physical thickness and a greatly reduced effective equivalent thickness (Tox). Additionally, since the gate dielectric layer 102 has such a sufficient physical thickness, it is possible to suppress the problems such as increase in current leakage or reduction in reliability of the gate dielectric layer 102.

Meanwhile, the gate dielectric layer 102 may comprise a silicon-hafnium based composite oxide which can be expressed by [(SiO₂)x(HfO₂)y]. Here, x and y can be selected to be in the range of 1˜10, respectively. Since the silicon-hafnium based composite oxide also has a higher dielectric constant than the silicon oxide, the gate dielectric layer 102 comprising the silicon-hafnium based composite oxide can provide the advantageous effects as described above.

The silicon-hafnium based composite oxide of the gate dielectric layer 102 is preferably formed by the atomic layer deposition. When the silicon-hafnium based composite oxide is formed through the atomic layer deposition, the crystallization of the silicon-hafnium based composite oxide is suppressed so that a stable Vt can be secured, thereby enhancing the reliability of the semiconductor device.

There will be described hereinafter one example of forming the gate dielectric layer 102 comprising the silicon-hafnium based composite oxide by the atomic layer deposition.

First, silicon tetrachloride (SiCl₄) gas or hexachlorodisilane (Si₂Cl₆) gas as a source of the silicon oxide is supplied into a reaction chamber for 0.1 second˜10 seconds such that silicon atoms are adsorbed onto the surface of the semiconductor substrate 100. Then, an inert gas such as nitrogen or argon is supplied into the reaction chamber for 0.1 second˜10 seconds to remove the remaining source gas.

Next, H₂O as a reaction gas is supplied into the reaction chamber for 0.1˜10 seconds to adsorb an oxygen atomic layer onto the silicon atomic layer formed on the semiconductor layer 100. As a result, a silicon oxide is formed on the semiconductor layer 100. Then, the inert gas such as nitrogen or argon is supplied into the reaction chamber for 0.1 second˜10 seconds to remove the remaining reaction gas.

Next, TEMAH gas [Hf(NC₂H₅CH₃)₄], TDMAH gas [Hf(N(CH₃)₂]₄ or TDEAH gas [Hf(N(C₂H₅)₂]₄ is supplied as a source gas of the hafnium oxide into the reaction chamber for 0.1 second˜10 seconds such that hafnium atoms are adsorbed onto the semiconductor substrate 100. Then, the inert gas such as nitrogen or argon is supplied into the reaction chamber for 0.1 second˜10 seconds to remove the remaining source gas.

Finally, H₂O as the reaction gas is supplied into the reaction chamber for 0.1 second˜10 seconds to adsorb an oxygen atomic layer onto the hafnium atomic layer formed on the semiconductor layer 100. Then, the inert gas such as nitrogen or argon is supplied into the reaction chamber for 0.1 second˜10 seconds to remove the remaining reaction gas. As a result; both silicon oxide and hafnium oxide are formed on the semiconductor substrate 100, so that the silicon-hafnium based composite oxide expressed by [(SiO₂)x(HfO₂)y] is formed as a single molecular layer.

The process described above can be performed under typical conditions for atomic layer deposition, for example, at a pressure of 0.1 Torr˜10 Torr and a temperature of 25° C.˜500° C. In addition, since the deposited thickness of the silicon-hafnium based composite oxide is increased by repeating the above process for several cycles, it is possible to control the thickness of the silicon-hafnium based composite oxide by adjusting the number of process cycles.

As described above, it is possible to form the gate dielectric layer 102 comprising the silicon-hafnium based composite oxide via the atomic layer deposition. The gate dielectric layer 102 preferably has a thickness of 300 Å or less.

In the description above, the process forms the gate dielectric layer 102 which comprises the silicon oxide in addition to the hafnium oxide, for example, the silicon-hafnium based composite oxide. Alternatively, the gate dielectric layer 102 may comprise other materials having a high dielectric constant in addition to the hafnium oxide. For example, the gate dielectric layer 102 may comprise the hafnium oxide, and at least one oxide selected from the group consisting of aluminum oxides, tantalum oxides, titanium oxides, and strontium titanium oxides.

Even in this case, the gate dielectric layer 102 has a higher dielectric constant than that of the conventional technology wherein the dielectric layer is formed using the silicon oxide. As a result, the gate dielectric layer 102 has a sufficient physical thickness while being greatly reduced in effective equivalent thickness (Tox), enabling significant improvement in characteristics of the transistor. Furthermore, the hafnium oxide and the other materials having such a high dielectric constant are formed by the atomic layer deposition so that the crystallization of the gate dielectric layer 102 is suppressed, thereby enhancing the reliability of the semiconductor device.

Meanwhile, after forming the gate dielectric layer 102, a gate electrode 104 is formed over the gate dielectric layer 102 as shown in FIG. 1b. At this time, the gate electrode 104 preferably comprises a hafnium nitride.

As described above, when forming the gate electrode 104 using such a hafnium nitride, it is possible to efficiently reduce the resistance of the gate electrode 104. In addition, since there is no need of using the doped polysilicon layer for the gate electrode 104, it is possible to avoid depletion of the gate electrode 104 or high topology of the gate electrode 104, whereby the increase in parasite capacitance and the deterioration of the refresh characteristics can be suppressed.

The gate electrode 104 preferably comprises the hafnium nitride having a work function of 4.5 eV˜4.6 eV. As such, when the gate electrode 104 comprises the hafnium nitride having the work function near a mid band-gap energy, a surface channel is formed through suitable adjustment of Vt in n-MOS and p-MOS transistors, thereby suppressing the short channel effect caused by high integration of the semiconductor device. Therefore, it is possible to suppress the short channel effect without employing the dual poly gate process.

The hafnium nitride of the gate electrode 104 can also be formed by the atomic layer deposition. As such, when the gate electrode 104 is formed by depositing the hafnium nitride through the atomic layer deposition, it is possible to continuously form the gate dielectric layer 102 and the gate electrode 104 in a single chamber. As a result, the process of forming the transistor of the semiconductor device and the structure of an apparatus therefor can be simplified.

There will be described hereinafter one example of forming the gate electrode 104 comprising the hafnium nitride by the atomic layer deposition.

First, TEMAH gas [Hf(NC₂H₅CH₃)₄], TDMAH gas [Hf(N(CH₃)₂]₄ or TDEAH gas [Hf(N(C₂H5)₂]₄ is supplied as a source of the hafnium-into the reaction chamber for 0.1 second˜10 seconds such that hafnium atoms are adsorbed onto the gate dielectric layer 102. Then, the inert gas such as nitrogen or argon is supplied into the reaction chamber for 0.1 second˜10 seconds to remove the remaining source gas.

Then, NH3 as a reaction gas is supplied into the reaction chamber for 0.1˜10 seconds to adsorb a nitrogen atomic layer onto the hafnium atomic layer formed on the surface of the gate dielectric layer 102, followed by supplying the inert gas such as nitrogen or argon into the reaction chamber for 0.1 second˜10 seconds to remove the remaining reaction gas. As a result, the hafnium nitride is formed in a single molecular layer on the gate dielectric layer 102.

The above process can also be performed in the typical condition for the atomic layer deposition, for example, at a pressure of 0.1 Torr˜10 Torr and a temperature of 25° C.˜500° C. In addition, since the deposited thickness of the hafnium nitride is increased by repeating the above process for several cycles, it is possible to control the thickness of the hafnium nitride by adjusting the number of process cycles.

As described above, it is possible to form the gate electrode 104 comprising the hafnium nitride via the atomic layer deposition. The gate electrode 104 may have a thickness of 2,000 Å or less.

Meanwhile, the process of forming the gate electrode 104 comprising the hafnium nitride through the atomic layer deposition can be carried out continuously after forming the gate dielectric layer 102 through the atomic layer deposition in the same reaction chamber. In this case, the processes can be performed by changing the source gases and the reaction gases at the same temperature and pressure. As a result, the process of forming the transistor of the semiconductor device and the structure of an apparatus therefor can be simplified.

After forming the gate electrode 104, a gate stack is formed by patterning the gate dielectric layer 102 and the gate electrode 104 as shown in FIG. 1c. Patterning of the gate dielectric layer 102 and the gate electrode 104 can be performed in such a way to form a photoresist pattern so as to define a region for the gate stack on the gate electrode 104, followed by etching the gate dielectric layer 102 and the gate electrode 104.

With the above processes, the transistor of the semiconductor device can be formed.

The embodiments and the accompanying drawings have been described for illustrative purposes and the invention is limited only by the following claims. Further, those skilled in the art will appreciate that various modifications, additions, and substitutions are allowed without departing from the scope and spirit of the invention according to the accompanying claims.

What is claimed is:

1. A transistor of a semiconductor device, comprising:
a gate dielectric layer formed over a semiconductor substrate and comprising a hafnium oxide; and
a gate electrode formed over the gate dielectric layer.

2. The transistor according to claim 1, wherein the gate electrode comprises a hafnium nitride.

3. The transistor according to claim 1, wherein the gate dielectric layer comprises the hafnium oxide and a silicon oxide.

4. The transistor according to claim 1, wherein the gate dielectric layer comprises a silicon-hafnium based composite oxide of the formula [(SiO₂)ₓ(HfO₂)_{y}] wherein 1≦x or y≦10.

5. The transistor according to claim 4, wherein the silicon-hafnium based composite oxide is formed by atomic layer deposition.

6. The transistor according to claim 1, wherein the gate dielectric layer comprises:
the hafnium oxide; and
at least one oxide selected from the group consisting of aluminum oxides, tantalum oxides, titanium oxides, and strontium titanium oxides.

7. The transistor according to claim 2, wherein the hafnium nitride has a work function of 4.5 eV˜4.6 eV.

8. The transistor according to claim 2, wherein the hafnium nitride is formed by atomic layer deposition.

9. The transistor according to claim 1, wherein the gate dielectric layer has a thickness of 300 Å or less.

10. The transistor according to claim 2, wherein the gate electrode has a thickness of 2,000 Å or less.

11. A method for manufacturing a transistor of a semiconductor device, comprising:
forming a gate dielectric layer over a semiconductor substrate, the gate dielectric layer comprising a hafnium oxide;
forming a gate electrode over the gate dielectric layer; and
patterning the gate dielectric layer and the gate electrode to form a gate stack.

12. The method according to claim 11, wherein the gate electrode comprises a hafnium nitride.

13. The method according to claim 11, wherein the gate dielectric layer comprises the hafnium oxide and a silicon oxide.

14. The method according to claim 1 1, wherein the gate dielectric layer comprises a silicon-hafnium based composite oxide of the formula [(SiO₂)ₓ(HfO₂)_{y}] wherein 1≦x or y≦10.

15. The method according to claim 14, comprising forming the silicon-hafnium based composite oxide by atomic layer deposition.

16. The method according to claim 11, wherein the gate dielectric layer comprises:
the hafnium oxide; and
at least one oxide selected from the group consisting of aluminum oxides, tantalum oxides, titanium oxides, and strontium titanium oxides.

17. The method according to claim 12, wherein the hafnium nitride has a work function of 4.5 eV˜4.6 eV.

18. The method according to claim 12, comprising forming the hafnium nitride atomic layer deposition.

19. The method according to claim 12, comprising continuously forming the gate dielectric layer and the gate electrode by atomic deposition in the same chamber.

20. The method according to claim 11, wherein the gate dielectric layer has a thickness of 300 Å or less.

21. The method according to claim 12, wherein the gate electrode has a thickness of 2,000 Å or less.
